(19) United States
(12) Patent Application Publication
(10) Pub. No.: US 2022/0088717 A1
(43) Pub. Date: Mar. 24, 2022

(54) WAFER MANUFACTURING METHOD

(71) Applicant: DISCO CORPORATION, Tokyo (JP)

(72) Inventor: Kazuya HIRATA, Tokyo (JP)

(21) Appl. No.: 17/446,499

(22) Filed: Aug. 31, 2021

(30) Foreign Application Priority Data
Sep. 18, 2020 (JP) 2020-157139

(51) Int. Cl. B23K 26/364

(52) U.S. Cl. CPC B23K 26/364

(57) ABSTRACT

A wafer manufacturing method includes a Z-coordinate measurement step of deeming a separation layer to be formed as an XY plane and measuring a height Z_{(X, Y)} of an upper surface of an ingot to be irradiated with a laser beam, corresponding to the X-coordinate and the Y-coordinate, and a calculation step of defining a Z-coordinate of the separation layer to be formed as Z₀ and calculating a difference from the measured height Z_{(X, Y)} (Z_{(X, Y)}-Z₀) to obtain a Z-coordinate of a beam condenser. A separation layer is formed by relatively moving the beam condenser in an X-axis direction and a Y-axis direction. The beam condenser is moved in a Z-axis direction on the basis of the Z-coordinate obtained in the calculation step to position a focal point to Z₀, and the separation layer is formed. A wafer is separated from the ingot.

### BACKGROUND OF THE INVENTION

### Field of the Invention

The present invention relates to a wafer manufacturing method in which a focal point of a laser beam with a wavelength having transmissibility with respect to a semiconductor ingot (hereinafter, abbreviated simply as an ingot) is positioned inside the ingot from an end surface of the ingot, the ingot is irradiated with the laser beam to form a separation layer, and a wafer is manufactured from the separation layer.

### Description of the Related Art

A wafer on which plural devices such as integrated circuits (ICs) and large scale integration (LSI) circuits are formed on a front surface in such a manner as to be marked out by plural planned dividing lines that intersect is divided into individual device chips by a dicing apparatus or a laser processing apparatus. The respective device chips obtained by the dividing are used for pieces of electrical equipment such as portable phones and personal computers.

A silicon (Si) substrate on which the devices are formed is formed through slicing of an Si ingot into a thickness of approximately 1 mm by a cutting apparatus including an inner diameter blade, a wire saw, or the like, lapping, and polishing (for example, refer to Japanese Patent Laid-open No. 2000-94221).

Moreover, a single-crystal silicon carbide (SiC) substrate on which power devices, light emitting diodes (LEDs), or the like are formed is also formed similarly to the above description. However, there is a problem that, when a wafer is manufactured through cutting an SiC ingot by a wire saw and polishing a front surface and a back surface of a cut piece, substantially half of the SiC ingot is discarded and this is uneconomical. Thus, the present applicant has proposed a technique in which a focal point of a laser beam having transmissibility with respect to single-crystal SiC is positioned inside an SiC ingot, the SiC ingot is irradiated with the laser beam to form a separation layer at a planned cutting plane, and the SiC ingot and the wafer are separated from each other along the planned cutting plane at which the separation layer has been formed (for example, refer to Japanese Patent Laid-open No. 2016-111143).

### SUMMARY OF THE INVENTION

Although the technique disclosed in Japanese Patent Laid-open No. 2016-111143 enables efficient manufacture of wafers from an ingot, there is a problem that the separation layer slightly bends.

Thus, an object of the present invention is to provide a wafer manufacturing method that can prevent a separation layer from bending.

In accordance with an aspect of the present invention, there is provided a wafer manufacturing method in which a focal point of a laser beam with a wavelength having transmissibility with respect to a semiconductor ingot is positioned inside the semiconductor ingot from an end surface of the semiconductor ingot, the semiconductor ingot is irradiated with the laser beam to form a separation layer, and a wafer is manufactured from the separation layer. The wafer manufacturing method includes a preparation step of preparing a laser processing apparatus including a holding unit that holds the semiconductor ingot, a laser beam irradiation unit that includes a beam condenser capable of moving the focal point in a Z-axis direction and executes irradiation with the laser beam from the end surface of the semiconductor ingot held by the holding unit, an X-axis movement mechanism that relatively moves the holding unit and the beam condenser in an X-axis direction, and a Y-axis movement mechanism that relatively moves the holding unit and the beam condenser in a Y-axis direction; a Z-coordinate measurement step of deeming the separation layer to be formed as an XY plane and measuring a height Z_{(X, Y)} of an upper surface of the semiconductor ingot to be irradiated with the laser beam, corresponding to an X-coordinate and a Y-coordinate; a calculation step of defining a Z-coordinate of the separation layer to be formed as Z₀ and calculating a difference from the measured height Z_{(X, Y)} (Z_{(X, Y)}-Z₀) to obtain a Z-coordinate of the beam condenser; a separation layer forming step of actuating the X-axis movement mechanism and the Y-axis movement mechanism to relatively move the holding unit and the beam condenser in the X-axis direction and the Y-axis direction, moving the beam condenser in the Z-axis direction on the basis of the Z-coordinate obtained in the calculation step to position the focal point to Z₀, and forming the separation layer; and a wafer separation step of separating the wafer and the semiconductor ingot from each other at the separation layer.

Preferably, in the calculation step, when a numerical aperture of an objective lens of the beam condenser is defined as NA(sin θ), a focal length of the objective lens is defined as h, a refractive index of the semiconductor ingot is defined as n(sin θ/sin β), and a Z-coordinate of the objective lens is defined as Z, the Z-coordinate to which the objective lens is positioned is obtained by

$$Z = h + ( {Z}_{( X , Y )} - {Z}_{0} ) ( 1 - tan β / tan θ ) .$$

Preferably, the semiconductor ingot is an SiC ingot, and the separation layer forming step includes a processing feed step of executing processing feed of the holding unit and the beam condenser relatively in the X-axis direction in such a manner that a direction orthogonal to a direction in which a c-plane tilts with respect to an end surface of the SiC ingot and an off-angle is formed is aligned with the X-axis direction, and an indexing feed step of executing indexing feed of the holding unit and the beam condenser relatively in the Y-axis direction.

Preferably, the semiconductor ingot is an Si ingot, in the separation layer forming step, a crystal plane (100) is employed as an end surface of the Si ingot, and the separation layer forming step includes a processing feed step of executing processing feed of the holding unit and the beam condenser relatively in the X-axis direction in such a manner that a direction <110> parallel to an intersection line at which a crystal plane {100} and a crystal plane {111} intersect or a direction [110] orthogonal to the intersection line is aligned with the X-axis direction, and an indexing feed step of executing indexing feed of the holding unit and the beam condenser relatively in the Y-axis direction.

According to the wafer manufacturing method of the present invention, the separation layer can be formed at the XY plane identified based on the Z₀ coordinate position, and the separation layer can be prevented from bending.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1A is a perspective view of an SiC ingot;

FIG. 1B is a plan view of the SiC ingot illustrated in FIG. 1A;

FIG. 1C is a front view of the SiC ingot illustrated in FIG. 1A;

FIG. 2A is a perspective view of an Si ingot;

FIG. 2B is a plan view of the Si ingot illustrated in FIG. 2A;

FIG. 3 is a perspective view of a laser processing apparatus;

FIG. 4 is a schematic diagram illustrating a configuration of the laser processing apparatus illustrated in FIG. 3;

FIG. 5A is a perspective view illustrating a state in which the SiC ingot illustrated in FIGS. 1A to 1C is adjusted to a predetermined orientation in a Z-coordinate measurement step;

FIG. 5B is a perspective view illustrating a state in which the Si ingot illustrated in FIGS. 2A and 2B is adjusted to a predetermined orientation in the Z-coordinate measurement step;

FIG. 5C is a perspective view illustrating a state in which the Si ingot illustrated in FIGS. 2A and 2B is adjusted to another orientation in the Z-coordinate measurement step;

FIG. 6 is a table illustrating data of a measured height Z_{(X, Y)} of an upper surface of the ingot;

FIG. 7 is a schematic diagram of a pulse laser beam with which the ingot is irradiated from an objective lens of a beam condenser;

FIG. 8A is a perspective view illustrating a state in which a separation layer forming step is being executed for the SiC ingot illustrated in FIGS. 1A to 1C;

FIG. 8B is a side view illustrating the state in which the separation layer forming step illustrated in FIG. 8A is being executed;

FIG. 8C is a sectional view of the SiC ingot in which a separation layer has been formed;

FIG. 9A is a perspective view illustrating a state in which the separation layer forming step is being executed for the Si ingot illustrated in FIGS. 2A and 2B;

FIG. 9B is a side view illustrating the state in which the separation layer forming step illustrated in FIG. 9A is being executed;

FIG. 9C is a sectional view of the Si ingot in which a separation layer has been formed; and

FIG. 10 is a perspective view illustrating a state in which a wafer separation step is being executed.

### DETAILED DESCRIPTION OF THE PREFERRED EMBODIMENT

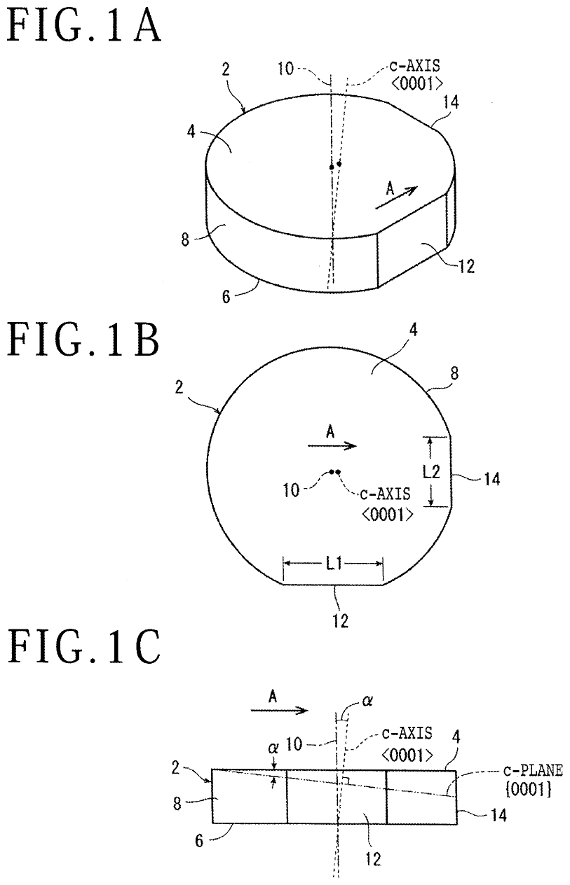

A preferred embodiment of the present invention will be described below with reference to the drawings. In FIGS. 1A to 1C, a circular columnar silicon carbide (SiC) ingot 2 that can be used for the wafer manufacturing method of the present invention is illustrated. The SiC ingot 2 is formed from hexagonal single-crystal SiC. The SiC ingot 2 has a circular first end surface 4, a circular second end surface 6 on a side opposite to the first end surface 4, a circumferential surface 8 located between the first end surface 4 and the second end surface 6, a c-axis (<0001> direction) that reaches the second end surface 6 from the first end surface 4, and a c-plane ({0001} plane) orthogonal to the c-axis. At least the first end surface 4 is planarized by grinding or polishing to such an extent that incidence of a laser beam is not precluded.

In the SiC ingot 2, the c-axis is inclined with respect to a perpendicular line 10 to the first end surface 4, and an off-angle α (for example, α=1, 3, or 6 degrees) is formed by the c-plane and the first end surface 4. A direction in which the off-angle α is formed is indicated by an arrow A in FIGS. 1A to 1C. Moreover, in the circumferential surface 8 of the SiC ingot 2, a first orientation flat 12 and a second orientation flat 14 that both represent a crystal orientation and have a rectangular shape are formed. The first orientation flat 12 is parallel to a direction A in which the off-angle α is formed, and the second orientation flat 14 is orthogonal to the direction A in which the off-angle α is formed. As illustrated in FIG. 1B, as viewed from above, a length L2 of the second orientation flat 14 is shorter than a length L1 of the first orientation flat 12 (L2<L1).

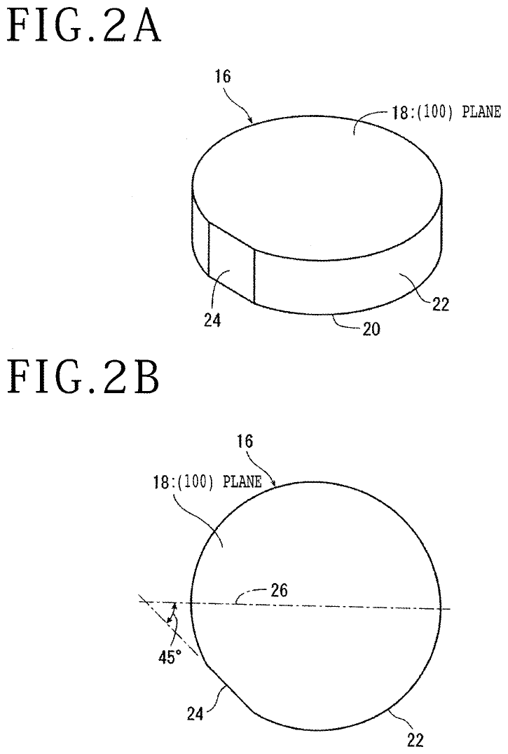

The ingot that can be used for the wafer manufacturing method of the present invention is not limited to the SiC ingot 2 and may be a circular columnar silicon (Si) ingot 16 illustrated in FIGS. 2A and 2B, for example. The Si ingot 16 has a circular first end surface 18 obtained by making a crystal plane (100) be an end surface, a circular second end surface 20 on a side opposite to the first end surface 18, and a circumferential surface 22 located between the first end surface 18 and the second end surface 20. At least the first end surface 18 is planarized by grinding or polishing to such an extent that incidence of a laser beam is not precluded. A rectangular orientation flat 24 that represents a crystal orientation is formed in the circumferential surface 22 of the Si ingot 16. The orientation flat 24 is positioned in such a manner that an angle with respect to an intersection line 26 at which a crystal plane {100} and a crystal plane {111} intersect is 45°.

In the present embodiment, first, a preparation step of preparing a laser processing apparatus is executed. This laser processing apparatus includes a holding unit that holds an ingot, a laser beam irradiation unit that includes a beam condenser capable of moving a focal point in a Z-axis direction and executes irradiation with a laser beam from an end surface of the ingot held by the holding unit, an X-axis movement mechanism that relatively moves the holding unit and the beam condenser in an X-axis direction, and a Y-axis movement mechanism that relatively moves the holding unit and the beam condenser in a Y-axis direction.

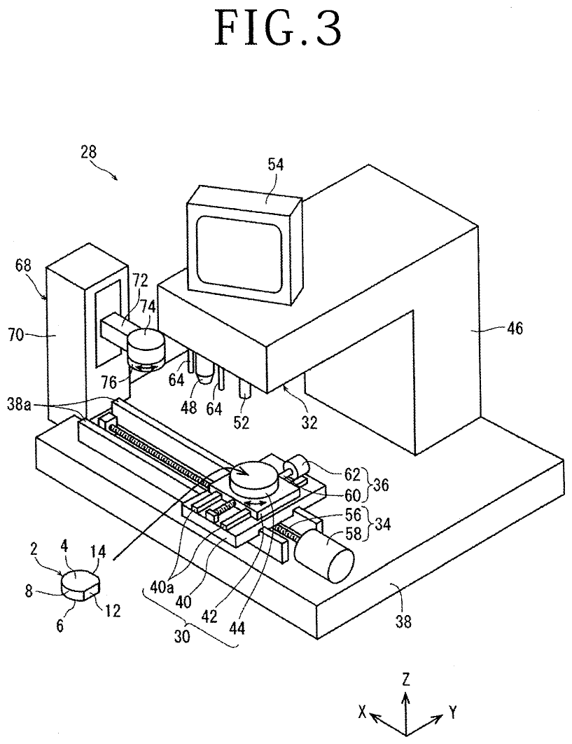

In the preparation step, for example, a laser processing apparatus 28 illustrated in FIG. 3 can be prepared. The laser processing apparatus 28 includes a holding unit 30, a laser beam irradiation unit 32, an X-axis movement mechanism 34, and a Y-axis movement mechanism 36.

As illustrated in FIG. 3, the holding unit 30 includes an X-axis movable plate 40 mounted over a base 38 movably in the X-axis direction, a Y-axis movable plate 42 mounted over the X-axis movable plate 40 movably in the Y-axis direction, a holding table 44 rotatably mounted on an upper surface of the Y-axis movable plate 42, and a motor (not illustrated) that rotates the holding table 44. The X-axis direction is a direction indicated by an arrow X in FIG. 3. The Y-axis direction is a direction indicated by an arrow Y in FIG. 3 and is a direction orthogonal to the X-axis direction. A plane defined by the X-axis direction and the Y-axis direction is substantially horizontal. Further, a direction indicated by an arrow Z in FIG. 3 is an upward-downward direction orthogonal to each of the X-axis direction and the Y-axis direction.

Moreover, in the holding unit 30, an ingot is held by an upper surface of the holding table 44 through an appropriate adhesive (for example, epoxy resin-based adhesive). Alternatively, plural suction holes may be formed in the upper surface of the holding table 44, and the ingot may be held under suction by a suction force generated on the upper surface of the holding table 44.

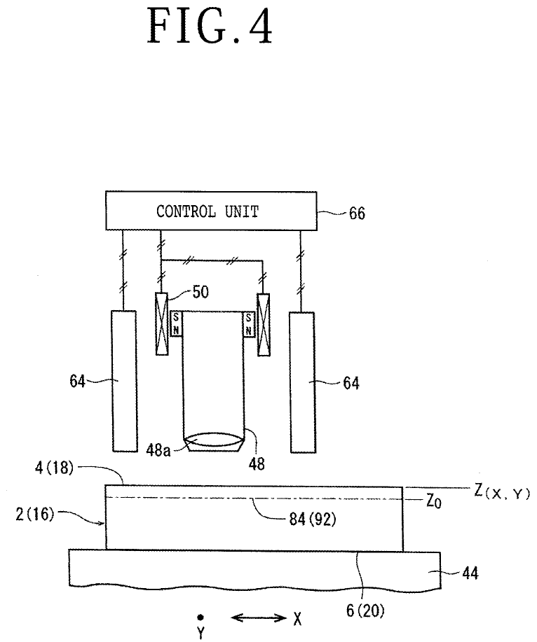

Description will be made with reference to FIGS. 3 and 4. The laser beam irradiation unit 32 includes a housing 46 (see FIG. 3) that extends upward from an upper surface of the base 38 and subsequently extends substantially horizontally, a laser oscillator (not illustrated) incorporated in the housing 46, a beam condenser 48 (see FIGS. 3 and 4) mounted on a lower surface of a tip of the housing 46 in such a manner as to be capable of rising and lowering, and a raising-lowering mechanism 50 (see FIG. 4) that raises and lowers the beam condenser 48.

The laser oscillator oscillates a pulse laser with a wavelength having transmissibility with respect to the ingot. As illustrated in FIG. 4, the beam condenser 48 has an objective lens 48a that focuses a pulse laser beam emitted from the laser oscillator on the ingot held by the holding unit 30. The raising-lowering mechanism 50 can be configured from a voice coil motor or a linear motor, for example. Moreover, in the laser beam irradiation unit 32, a focal point of the pulse laser beam can be moved in the Z-axis direction by adjusting a Z-coordinate of the objective lens 48a through raising or lowering the beam condenser 48 by the raising-lowering mechanism 50. In addition, as illustrated in FIG. 3, an imaging unit 52 that images the ingot held by the holding unit 30 is mounted on the lower surface of the tip of the housing 46, and a display unit 54 that displays an image captured by imaging by the imaging unit 52 is disposed on an upper surface of the housing 46.

The description will be continued with reference to FIG. 3. The X-axis movement mechanism 34 has a ball screw 56 that is coupled to the X-axis movable plate 40 and extends in the X-axis direction and a motor 58 that rotates the ball screw 56. The X-axis movement mechanism 34 converts rotational motion of the motor 58 to linear motion by the ball screw 56 and transmits the linear motion to the X-axis movable plate 40 to move the X-axis movable plate 40 in the X-axis direction relative to the beam condenser 48 along guide rails 38a on the base 38.

The Y-axis movement mechanism 36 has a ball screw 60 that is coupled to the Y-axis movable plate 42 and extends in the Y-axis direction and a motor 62 that rotates the ball screw 60. The Y-axis movement mechanism 36 converts rotational motion of the motor 62 to linear motion by the ball screw 60 and transmits the linear motion to the Y-axis movable plate 42 to move the Y-axis movable plate 42 in the Y-axis direction relative to the beam condenser 48 along guide rails 40a on the X-axis movable plate 40.

The laser processing apparatus 28 further includes Z-coordinate measuring units 64 (see FIGS. 3 and 4) that measure a height of an upper surface of the ingot, a control unit 66 (see FIG. 4) that controls actuation of the laser processing apparatus 28, and a separation mechanism 68 (see FIG. 3) that separates the ingot and a wafer from each other at a separation layer.

As the Z-coordinate measuring units 64, height measuring instruments of a publicly-known laser system or ultrasonic system can be used. In the present embodiment, a pair of Z-coordinate measuring units 64 are set on both sides of the beam condenser 48 in the X-axis direction. However, the number of Z-coordinate measuring units 64 may be one. The control unit 66 that can be configured from a computer includes a central processing unit (CPU) that executes calculation processing in accordance with a control program, a read-only memory (ROM) that stores the control program and so forth, and a readable-writable random access memory (RAM) that stores a calculation result and so forth (none of them is illustrated).

As illustrated in FIG. 3, the separation mechanism 68 includes a casing 70 that extends upward from end parts of the guide rails 38a on the base 38 and has a rectangular parallelepiped shape and an arm 72 that extends in the X-axis direction from a base end thereof mounted on the casing 70 in such a manner as to be capable of rising and lowering. An arm raising-lowering mechanism (not illustrated) that raises and lowers the arm 72 is incorporated in the casing 70. A motor 74 is attached to a tip of the arm 72, and a suction adhesion piece 76 is coupled to a lower surface of the motor 74 rotatably around an axis line that extends in the upward-downward direction. The suction adhesion piece 76 having a lower surface in which plural suction holes (not illustrated) are formed is connected to suction means (not illustrated) through a flow path. Moreover, ultrasonic vibration giving means (not illustrated) that gives ultrasonic vibrations to the lower surface of the suction adhesion piece 76 is incorporated in the suction adhesion piece 76.

After the preparation step is executed, a Z-coordinate measurement step is executed in which the separation layer to be formed is deemed as the XY plane and a height Z_{(X, Y)} of the upper surface of an ingot to be irradiated with the laser beam is measured corresponding to the X-coordinate and the Y-coordinate.

In the Z-coordinate measurement step, first, an ingot (it may be either the SiC ingot 2 or the Si ingot 16) is held by the upper surface of the holding table 44. Subsequently, the ingot 2 (16) is imaged from above by the imaging unit 52, and the holding table 44 is rotated and moved based on an image of the ingot 2 (16) captured by the imaging unit 52. As a result, the orientation of the ingot 2 (16) is adjusted to a predetermined orientation. In addition, a positional relation between the Z-coordinate measuring units 64 and the ingot 2 (16) is adjusted.

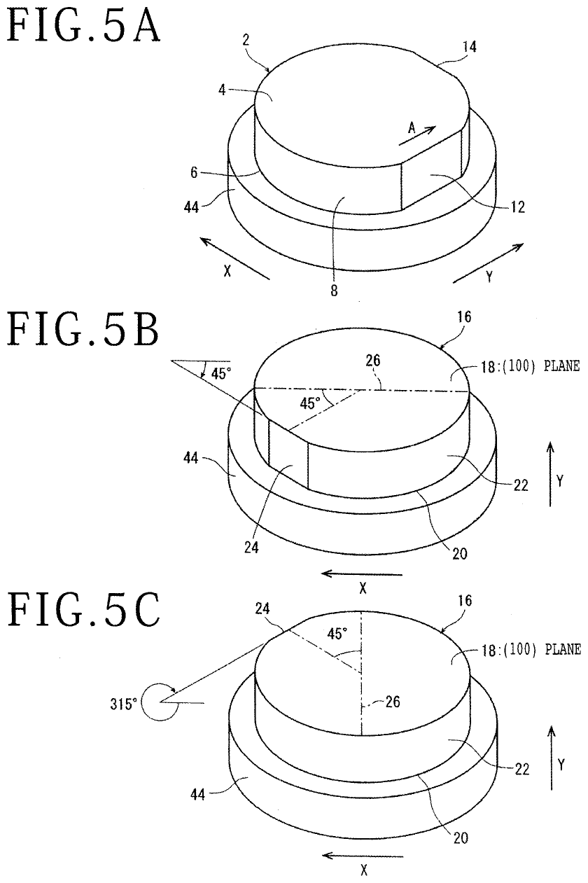

When the orientation of the ingot 2 (16) is adjusted to the predetermined orientation, in the case of the SiC ingot 2, as illustrated in FIG. 5A, the direction orthogonal to the direction A in which the off-angle α is formed is aligned with the X-axis direction by aligning the second orientation flat 14 with the X-axis direction. In the case of the Si ingot 16, as illustrated in FIG. 5B, the adjustment is executed in such a manner that an angle formed between the X-axis direction and the orientation flat 24 becomes 45°, and a direction <110> parallel to the intersection line 26 at which the crystal plane {100} and the crystal plane {111} intersect is aligned with the X-axis direction. Alternatively, in the case of the Si ingot 16, as illustrated in FIG. 5C, the adjustment may be executed in such a manner that the angle formed between the X-axis direction and the orientation flat 24 becomes 315°, and a direction [110] orthogonal to the intersection line 26 may be aligned with the X-axis direction.

Subsequently, by actuating either one of the pair of Z-coordinate measuring units 64 while moving the holding table 44 that holds the ingot 2 (16) in the X-axis direction by the X-axis movement mechanism 34, heights Z_{(X1, Y1)}, Z_{(X2, Y1)}, Z_{(X3, Y1)}, . . . , Z_{(Xm, Y1)} of the upper surface (in the present embodiment, the first end surface 4 (18)) of the ingot 2 (16) at coordinates (X₁, Y₁), (X₂, Y₁), (X₃, Y₁), . . . , (Xₘ, Y₁), respectively, are measured. The measured height of the upper surface of the ingot 2 (16) is the height of the upper surface of the ingot 2 (16) when the separation layer to be formed is deemed as the XY plane (reference plane).

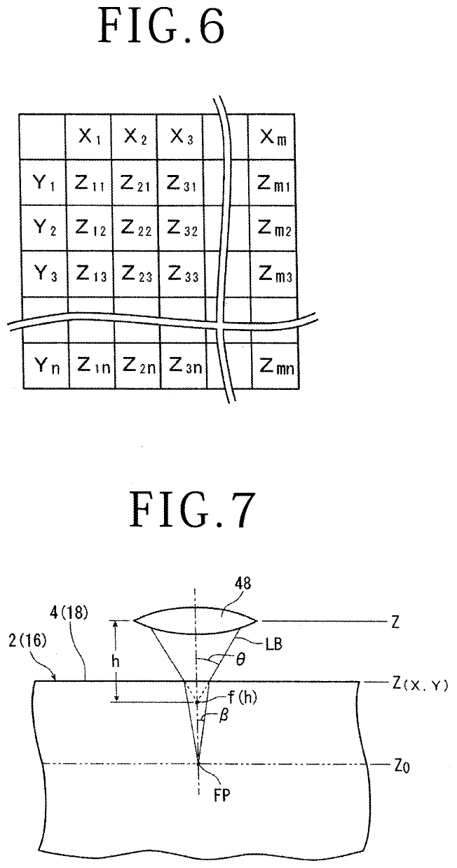

Subsequently, indexing feed of the holding table 44 is executed in the Y-axis direction by a predetermined pitch (Y₂-Y₁) by the Y-axis movement mechanism 36. Thereafter, the Z-coordinate measuring unit 64 is actuated while the holding table 44 is moved in the X-axis direction, and heights Z_{(X1, Y2)}, Z_{(X2, Y2)}, Z_{(X3, Y2)}, . . . , Z_{(Xm, Y2)} of the upper surface of the ingot 2 (16) at coordinates (X₁, Y₂), (X₂, Y₂), (X₃, Y₂), . . . , (Xₘ, Y₂), respectively, are measured. Then, while indexing feed of the holding table 44 is executed in the Y-axis direction to a coordinate Yₙ by a predetermined pitch (Yₙ-Yₙ₋₁), the height of the upper surface of the ingot 2 (16) is measured at plural points along the X-axis direction. As a result, data relating to the height Z_{(X, Y)} of the upper surface of the ingot 2 (16) like one illustrated in FIG. 6 is measured corresponding to the X-coordinate and the Y-coordinate, and the measured data is stored in the random access memory of the control unit 66.

After the Z-coordinate measurement step is executed, a calculation step of defining the Z-coordinate of the separation layer to be formed as Z₀ and calculating a difference from the measured height Z_{(X, Y)} (Z_{(X, Y)}-Z₀) to obtain the Z-coordinate of the beam condenser 48 is executed.

Description will be made with reference to FIG. 7. In the calculation step of the present embodiment, a numerical aperture of the objective lens 48a of the beam condenser 48 is defined as NA(sin θ), a focal length of the objective lens 48a is defined as h, a refractive index of the ingot 2 (16) is defined as n(sin θ/sin β), and the Z-coordinate of the objective lens 48a is defined as Z. In this case, the following expression holds.

$$( {Z}_{( X , Y )} - {Z}_{0} ) tan β = [ h - \{ Z - ( {Z}_{( X , Y )} - {Z}_{0} ) \} ] tan θ$$

When the above expression is transformed, the following expression (1) is obtained.

$$Expression ( 1 )$$

$$( {Z}_{( X , Y )} - {Z}_{0} ) tan β / tan θ = h - Z + ( {Z}_{( X , Y )} - {Z}_{0} )$$

$$Z = h + ( {Z}_{( X , Y )} - {Z}_{0} ) - ( {Z}_{( X , Y )} - {Z}_{0} ) tan β / tan θ$$

$$Z = h + ( {Z}_{( X , Y )} - {Z}_{0} ) ( 1 - tan β / tan θ )$$

The Z-coordinate to which the objective lens 48a of the beam condenser 48 is positioned is obtained by the above expression (1).

In the calculation step, based on the data relating to the height Z_{(X, Y)} of the upper surface of the ingot 2 (16) measured in the Z-coordinate measurement step, the Z-coordinate to which the objective lens 48a of the beam condenser 48 is positioned is calculated at all coordinates from the coordinates (X₁, Y₁) to the coordinates (Xₘ, Yₙ). By positioning the objective lens 48a of the beam condenser 48 to the Z-coordinate calculated in the calculation step at all points from the coordinates (X₁, Y₁) to the coordinates (Xₘ, Yₙ), a focal point FP of a pulse laser beam LB can be positioned to Z₀. In FIG. 7, a focus position of the objective lens 48a in air is indicated by a symbol f(h).

After the calculation step is executed, a separation layer forming step is executed in which the X-axis movement mechanism 34 and the Y-axis movement mechanism 36 are actuated to relatively move the holding unit 30 and the beam condenser 48 in the X-axis direction and the Y-axis direction, the beam condenser 48 is moved in the Z-axis direction on the basis of the Z-coordinate obtained in the calculation step, to position the focal point FP to Z₀, and a separation layer is then formed.

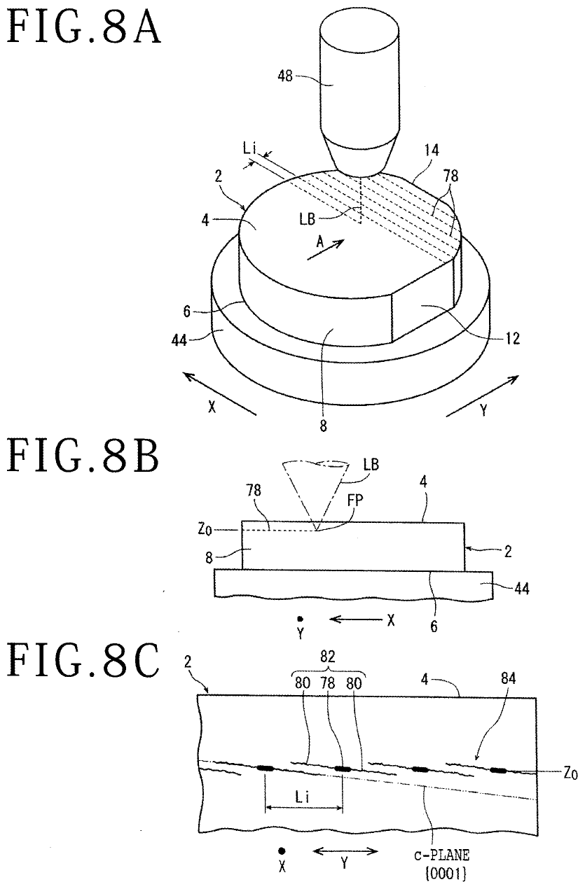

Regarding the separation layer forming step, description will be made individually for the case of executing it for the SiC ingot 2 and the case of executing it for the Si ingot 16. First, the case of executing the separation layer forming step for the SiC ingot 2 will be described with reference to FIGS. 8A to 8C. In the separation layer forming step, first, a positional relation between the beam condenser 48 and the SiC ingot 2 is adjusted. In addition, the objective lens 48a of the beam condenser 48 is positioned to the Z-coordinate calculated in the calculation step. As a result, the focal point FP (see FIG. 8B) of the pulse laser beam LB is positioned to the Z-coordinate (Z₀) of the separation layer to be formed. As is understood by referring to FIG. 8A, also in the separation layer forming step, the direction orthogonal to the direction A in which the off-angle α is formed is aligned with the X-axis direction as in the Z-coordinate measurement step.

Subsequently, while processing feed of the holding table 44 is executed by the X-axis movement mechanism 34 in the X-axis direction at a predetermined feed rate and the beam condenser 48 is moved in the Z-axis direction by the raising-lowering mechanism 50 on the basis of the Z-coordinate obtained in the calculation step, the SiC ingot 2 is irradiated with the pulse laser beam LB with a wavelength (for example, 1064 nm) having transmissibility with respect to the SiC ingot 2 (processing feed step). As a result, SiC separates into silicon (Si) and carbon (C), and the pulse laser beam LB with which irradiation is executed next is absorbed by previously-formed C, so that SiC separates into Si and C in a chain-reaction manner. In addition, a separation zone 82 arising from extension of cracks 80 that isotropically extend along the c-plane from a part 78 at which the separation into Si and C has occurred is formed.

In the processing feed step, the objective lens 48a of the beam condenser 48 is positioned to the Z-coordinate calculated in the calculation step. Thus, the focal point FP of the pulse laser beam LB can be positioned to Z₀ even when the height of the upper surface of the SiC ingot 2 is not constant due to existence of undulation in the upper surface of the SiC ingot 2. Therefore, the part 78 at which the separation into Si and C has occurred in the separation zone 82 is formed straight along the X-axis direction at the position of the coordinate Z₀.

Subsequently, indexing feed of the holding table 44 is executed by the Y-axis movement mechanism 36 in the Y-axis direction by a predetermined indexing feed amount Li (indexing feed step). The indexing feed amount Li is the same as the predetermined pitch (Yₙ-Yₙ₋₁) in the Z-coordinate measurement step. By alternately repeating the processing feed step and the indexing feed step, a separation layer 84 that is composed of plural separation zones 82 and has lowered strength can be formed at the XY plane identified based on the Z₀ coordinate position.

It is desirable that the indexing feed amount Li be set within a range that does not exceed a width of the cracks 80 and the cracks 80 adjacent in the Y-axis direction be caused to overlap with each other as viewed in the upward-downward direction. This can further reduce the strength of the separation layer 84, and separation of a wafer becomes easy in a wafer separation step to be described later.

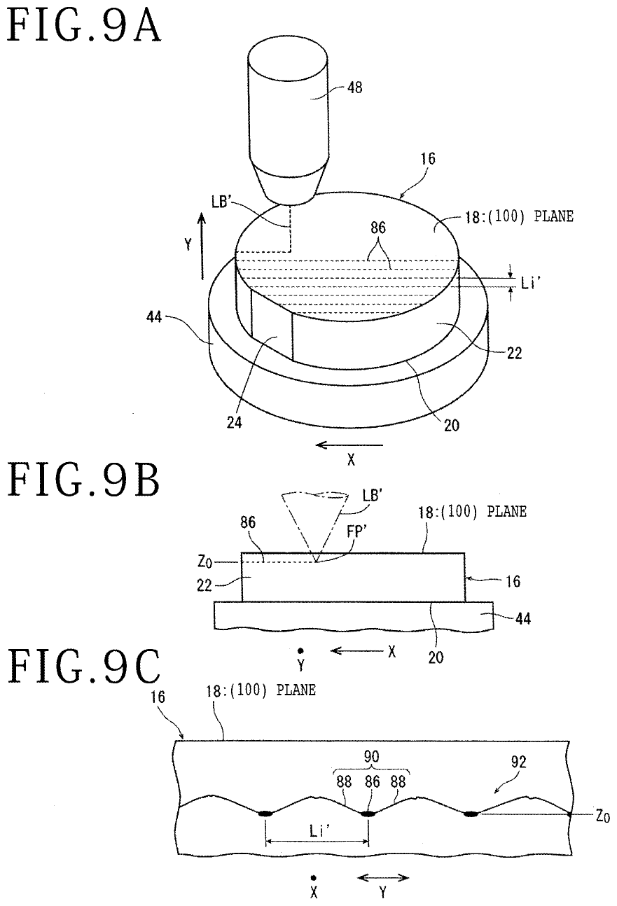

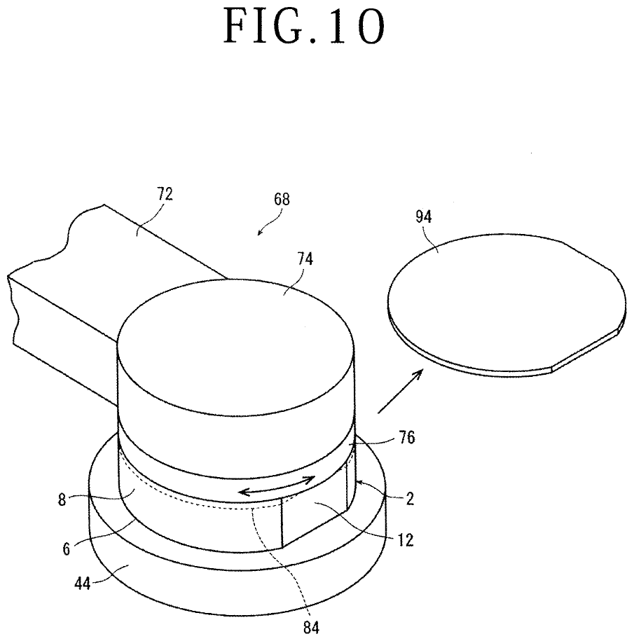

Next, the case of executing the separation layer forming step for the Si ingot 16 will be described with reference to FIGS. 9A to 9C. Also in the separation layer forming step for the Si ingot 16, first, the objective lens 48a of the beam condenser 48 is positioned to the Z-coordinate calculated in the calculation step. As a result, a focal point FP′ (see FIG. 9B) of a pulse laser beam LB′ is positioned to the Z-coordinate (Z₀) of the separation layer to be formed. As is understood by referring to FIG. 9A, also in the separation layer forming step for the Si ingot 16, the direction <110> parallel to the intersection line 26 at which the crystal plane {100} and the crystal plane {111} intersect is aligned with the X-axis direction as in the Z-coordinate measurement step. Alternatively, the direction [110] orthogonal to the intersection line 26 may be aligned with the X-axis direction although diagrammatic representation is not made.

Subsequently, while processing feed of the holding table 44 is executed by the X-axis movement mechanism 34 in the X-axis direction at a predetermined feed rate and the beam condenser 48 is moved in the Z-axis direction by the raising-lowering mechanism 50 on the basis of the Z-coordinate obtained in the calculation step, the Si ingot 16 is irradiated with the pulse laser beam LB′ with a wavelength (for example, 1342 nm) having transmissibility with respect to the Si ingot 16 (processing feed step). As a result, a crystal structure of the silicon is broken. In addition, a separation zone 90 arising from isotropic extension of cracks 88 along a (111) plane from a part 86 at which the crystal structure is broken is formed. The part 86 at which the crystal structure is broken in the separation zone 90 is formed straight along the X-axis direction at the position of the coordinate Z₀.

In the present embodiment, the holding table 44 and the beam condenser 48 are relatively moved in the direction <110> parallel to the intersection line 26 at which the crystal plane {100} and the crystal plane {111} intersect. However, the separation zone 90 similar to the above is formed also when the holding table 44 and the beam condenser 48 are relatively moved in the direction [110] orthogonal to the intersection line 26.

Subsequently, indexing feed of the holding table 44 is executed by the Y-axis movement mechanism 36 in the Y-axis direction by a predetermined indexing feed amount Li′ (indexing feed step). The indexing feed amount Li′ is the same as the predetermined pitch (Yₙ-Yₙ₋₁) in the Z-coordinate measurement step executed for the Si ingot 16. By alternately repeating the processing feed step and the indexing feed step, a separation layer 92 that is composed of plural separation zones 90 and has lowered strength can be formed at the XY plane identified based on the Z₀ coordinate position.

A slight gap may be set between the cracks 88 of the separation zones 90 adjacent in the Y-axis direction. However, it is preferable that the indexing feed amount Li′ be set within a range that does not exceed a width of the cracks 88 and the adjacent separation zones 90 be brought into contact with each other. This can couple the adjacent separation zones 90 to each other and further reduce the strength of the separation layer 92, and separation of a wafer becomes easy in the wafer separation step to be described later.

After the separation layer forming step is executed, the wafer separation step of separating the ingot 2 (16) and a wafer from each other at the separation layer 84 (92) is executed. An example in which the SiC ingot 2 and a wafer are separated from each other at the separation layer 84 will be described with reference to FIG. 10. In the wafer separation step, first, the holding table 44 is positioned below the suction adhesion piece 76 of the separation mechanism 68 by the X-axis movement mechanism 34. Subsequently, the arm 72 is lowered, and the lower surface of the suction adhesion piece 76 is brought into close contact with the upper surface of the SiC ingot 2. The suction means is then actuated to cause suction adhesion of the lower surface of the suction adhesion piece 76 to the upper surface of the SiC ingot 2. Subsequently, the ultrasonic vibration giving means is actuated to give ultrasonic vibrations to the lower surface of the suction adhesion piece 76. In addition, the suction adhesion piece 76 is rotated by the motor 74. This can separate the SiC ingot 2 and a wafer 94 from each other with use of the separation layer 84 as a point of origin. After the wafer 94 is separated, a separation surface of the SiC ingot 2 and a separation surface of the wafer 94 are planarized by grinding or polishing. Also when the Si ingot 16 and a wafer are separated from each other at the separation layer 92, the wafer separation step is executed similarly to the above description.

As described above, according to the wafer manufacturing method of the present embodiment, the separation layer 84 (92) can be formed at the XY plane identified based on the Z₀ coordinate position, and the separation layer 84 (92) can be prevented from bending. Moreover, because the separation layer 84 (92) does not bend, the wafer 94 that hardly involves undulation can be manufactured from the ingot 2 (16), and work of removing undulation of the manufactured wafer 94 can be shortened or omitted.

In the present embodiment, the example in which the Z-coordinate measurement step, the calculation step, and the separation layer forming step are separately executed has been described. However, the Z-coordinate measurement step, the calculation step, and the separation layer forming step may be concurrently executed. That is, the following operation may be executed. While the holding table 44 is moved toward one side in the X-axis direction (for example, left side in FIG. 4) by the X-axis movement mechanism 34, the height Z_{(X, Y)} of the upper surface of the ingot 2 (16) is measured by the Z-coordinate measuring unit 64 on the left side in FIG. 4 (Z-coordinate measurement step), the Z-coordinate of the beam condenser 48 is obtained by using the measured height Z_{(X, Y)} of the upper surface (calculation step), and the ingot 2 (16) is irradiated with a laser beam while the beam condenser 48 is moved in the Z-axis direction on the basis of the calculated Z-coordinate (separation layer forming step).

In the case of concurrently executing the Z-coordinate measurement step, the calculation step, and the separation layer forming step as above, it is preferable that the Z-coordinate measuring units 64 be disposed on both sides of the beam condenser 48 in the X-axis direction. Due to this, whichever of one side and the other side in the X-axis direction (left side and right side in FIG. 4) the holding table 44 is moved toward, the height of the upper surface of the ingot 2 (16) can be measured before the ingot 2 (16) is irradiated with the laser beam from the beam condenser 48. Therefore, in the case in which the Z-coordinate measuring units 64 are disposed on both sides of the beam condenser 48 in the X-axis direction, after processing feed of the holding table 44 is first executed toward one side in the X-axis direction to form the separation layer 84 (92) and subsequently indexing feed is executed, processing feed of the holding table 44 can be executed toward the other side in the X-axis direction to form the separation layer 84 (92). That is, the separation layer 84 (92) can be formed in both forward movement and backward movement of the holding table 44, and therefore, improvement in productivity can be sought.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A wafer manufacturing method in which a focal point of a laser beam with a wavelength having transmissibility with respect to a semiconductor ingot is positioned inside the semiconductor ingot from an end surface of the semiconductor ingot, the semiconductor ingot is irradiated with the laser beam to form a separation layer, and a wafer is manufactured from the separation layer, the wafer manufacturing method comprising:
a preparation step of preparing a laser processing apparatus including a holding unit that holds the semiconductor ingot, a laser beam irradiation unit that includes a beam condenser capable of moving the focal point in a Z-axis direction and executes irradiation with the laser beam from the end surface of the semiconductor ingot held by the holding unit, an X-axis movement mechanism that relatively moves the holding unit and the beam condenser in an X-axis direction, and a Y-axis movement mechanism that relatively moves the holding unit and the beam condenser in a Y-axis direction;
a Z-coordinate measurement step of deeming the separation layer to be formed as an XY plane and measuring a height Z_{(X, Y)} of an upper surface of the semiconductor ingot to be irradiated with the laser beam, corresponding to an X-coordinate and a Y-coordinate;
a calculation step of defining a Z-coordinate of the separation layer to be formed as Z₀ and calculating a difference from the measured height Z_{(X, Y)} (Z_{(X, Y)}-Z₀) to obtain a Z-coordinate of the beam condenser;
a separation layer forming step of actuating the X-axis movement mechanism and the Y-axis movement mechanism to relatively move the holding unit and the beam condenser in the X-axis direction and the Y-axis direction, moving the beam condenser in the Z-axis direction on a basis of the Z-coordinate obtained in the calculation step to position the focal point to Z₀, and forming the separation layer; and
a wafer separation step of separating the wafer and the semiconductor ingot from each other at the separation layer.

2. The wafer manufacturing method according to claim 1, wherein,
in the calculation step, when a numerical aperture of an objective lens of the beam condenser is defined as NA(sin θ), a focal length of the objective lens is defined as h, a refractive index of the semiconductor ingot is defined as n(sin θ/sin β), and a Z-coordinate of the objective lens is defined as Z,
the Z-coordinate to which the objective lens is positioned is obtained by
$$Z = h + ( {Z}_{( X , Y )} - {Z}_{0} ) ( 1 - tan β / tan θ ) .$$

3. The wafer manufacturing method according to claim 1, wherein
the semiconductor ingot is an SiC ingot, and
the separation layer forming step includes
a processing feed step of executing processing feed of the holding unit and the beam condenser relatively in the X-axis direction in such a manner that a direction orthogonal to a direction in which a c-plane tilts with respect to an end surface of the SiC ingot and an off-angle is formed is aligned with the X-axis direction, and
an indexing feed step of executing indexing feed of the holding unit and the beam condenser relatively in the Y-axis direction.

4. The wafer manufacturing method according to claim 1, wherein
the semiconductor ingot is an Si ingot,
in the separation layer forming step, a crystal plane (100) is employed as an end surface of the Si ingot, and
the separation layer forming step includes
a processing feed step of executing processing feed of the holding unit and the beam condenser relatively in the X-axis direction in such a manner that a direction <110> parallel to an intersection line at which a crystal plane {100} and a crystal plane {111} intersect or a direction [110] orthogonal to the intersection line is aligned with the X-axis direction, and
an indexing feed step of executing indexing feed of the holding unit and the beam condenser relatively in the Y-axis direction.
